(19) United States
(12) Patent Application Publication
(10) Pub. No.: US 2026/0061466 A1
(43) Pub. Date: Mar. 5, 2026

(54) ELECTROSTATIC PLATEN CLEANING DETECTION SYSTEM AND METHOD

(71) Applicant: Applied Materials, Inc., Santa Clara, CA (US)

(72) Inventors: Taichiro Ishizaka, Kumamoto-City (JP); Daisuke Matsubara, Kuwana-City (JP)

(21) Appl. No.: 18/818,829

(22) Filed: Aug. 29, 2024

(51) Int. Cl. B08B 13/00; B08B 7/00; H01J 37/20; H01J 37/30; H01J 37/32; H01L 21/683

(52) U.S. Cl. CPC B08B 13/00; B08B 7/0035; H01J 37/20; H01J 37/30; H01J 37/32715; H01J 2237/2007; H01J 2237/335

(57) ABSTRACT

A system and method to control the cleaning of an electrostatic platen is disclosed. A clamping voltage is applied to the electrostatic platen when a workpiece is not disposed on the top surface of the platen. Over time, the deposition of material on the clamping surface causes changes in the current that is supplied to the platen when the clamping voltage is applied. By monitoring the current in this manner, it is possible to terminate the cleaning process when a sufficient amount of deposited material has been removed. Additionally, by monitoring the current, it is also possible to determine when a cleaning process is warranted.

### FIELD

Embodiments of the present disclosure relate to electrostatic platens and systems and methods to determine when to initiate and end a cleaning process.

### BACKGROUND

Semiconductor devices are fabricated using a plurality of processes, including etching, implanting, and deposition to name only a few. In some of these processes, a workpiece may be disposed on an electrostatic platen, which provides an electrostatic force so as to clamp the workpiece in place. This electrostatic force is generated by electrodes disposed in the platen, which are energized in a specific sequence to provide the clamping force.

Over time, deposits may form on a clamping surface of the electrostatic platen. These deposits can be become problematic and interfere with proper clamping of the workpiece. For example, the deposited material may be conductive, allowing charges to move easily on the clamping surface of the platen. As a result, proper capacitance may not be generated between the electrostatic platen and the workpiece, resulting in insufficient electrostatic clamping force. Such deposits may also damage the backside of the workpiece and cause undesirable particles. In some instances, for plasma-based semiconductor processing tools such as an etch tool or deposition tool and other semiconductor processing tools, a cleaning process may be initiated after processing a certain number of workpieces. This may start the cleaning process too soon and hence lower the throughput of the tool or the number of workpieces processed per unit time. This may also prolong the cleaning process if there is no adequate end point detection which can also lower throughput.

The cleaning process for some plasma based tools may include a remote plasma clean where a gas such as NF₃ is ionized in a remote plasma chamber and a pressure gradient between the remote plasma source and the plasma processing chamber is used to move radicals into the processing chamber to clean the chamber and the clamping surface of the electrostatic platen.

For a beamline ion implanter, which is a type of a semiconductor processing apparatus, an ion beam may be directed toward the workpiece so as to implant ions and/or perform a precision material engineering application to a portion of the workpiece. After the workpiece has been processed, it may be removed from the platen and a new workpiece may be placed on the platen. However, in the time between the processed workpiece being removed and the new workpiece being placed on the platen, the platen is exposed to the environment within the process chamber. This may allow particles to become deposited on the surface of the platen A cleaning process for the clamping surface of an electrostatic platen of a beamline ion implanter may include directing an argon ion beam at the clamping surface positioned at a defined larger tile angle relative to the ion beam to intentionally create a glancing blow of the ion beam that sputter cleans the clamping surface of the electrostatic platen.

For any electrostatic platen, cleaning or replacement of the platen may be advisable when it becomes sufficiently dirty with undesired deposited materials. However, platens are expensive to replace and they are often cleaned. Additionally, it may be difficult to clean the platen without venting the process chamber, which significantly affects throughput.

Thus, a system that allows the platen to be cleaned without venting the process chamber would be beneficial. Further, it would be advantageous if this cleaning process had a defined endpoint. It would also be advantageous to detect the need to perform a cleaning operation.

### SUMMARY

A system and method to control the cleaning of an electrostatic platen is disclosed. A clamping voltage is applied to the electrostatic platen when a workpiece is not disposed on the top surface of the platen. Over time, the deposition of material on the clamping surface causes changes in the current that is supplied to the platen when the clamping voltage is applied. By monitoring the current in this manner, it is possible to terminate the cleaning process when a sufficient amount of deposited material has been removed. Additionally, by monitoring the current, it is also possible to determine when a cleaning process is warranted.

According to one embodiment, a method of cleaning an electrostatic platen is disclosed. The method comprises performing a cleaning process on a clamping surface of the electrostatic platen; applying a clamping voltage to the electrostatic platen using an electrode power supply while the cleaning process is ongoing; monitoring a characteristic of current being supplied by the electrode power supply to the electrostatic platen; and performing an action when the characteristic of current is less than a predetermined threshold. In some embodiments, the characteristic of current comprises peak current. In some embodiments, the characteristic of current comprises RMS current. In some embodiments, a reference value of the characteristic of current is determined by applying a clamping voltage to the electrostatic platen when first installed, and the predetermined threshold is determined based on the reference value of the characteristic of current. In certain embodiments, the predetermined threshold is a percentage of the reference value added to the reference value. In certain embodiments, the predetermined threshold is a fixed value added to the reference value. In some embodiments, the action comprises terminating the cleaning process. In some embodiments, the action comprises providing an indication that the characteristic of current is less than the predetermined threshold to an operator. In some embodiments, the cleaning process comprises directing an argon ion beam toward the clamping surface of the electrostatic platen. In some embodiments, the cleaning process comprises utilizing a cleaning plasma in a plasma chamber containing the electrostatic platen.

According to another embodiment, a method of determining when to clean an electrostatic platen is disclosed. The method comprises removing a workpiece from the electrostatic platen; applying a clamping voltage to the electrostatic platen using an electrode power supply after removing the workpiece; monitoring a characteristic of current being supplied by the electrode power supply to the electrostatic platen; and determining that the electrostatic platen should be cleaned when the characteristic of current is greater than a predetermined threshold. In some embodiments, the characteristic of current comprises peak current. In some embodiments, the characteristic of current comprises RMS current. In some embodiments, a reference value of the characteristic of current is determined by applying a clamping voltage to the electrostatic platen when first installed, and the predetermined threshold is determined based on the reference value of the characteristic of current. In certain embodiments, the predetermined threshold is a percentage of the reference value added to the reference value or is a fixed value added to the reference value.

According to another embodiment, a semiconductor processing apparatus is disclosed. The semiconductor processing apparatus comprises an electrostatic platen adapted to electrostatically clamp a workpiece; an electrode power supply to provide a clamping voltage to the electrostatic platen; and a controller, wherein the controller is configured to: apply a clamping voltage to the electrostatic platen using the electrode power supply while a cleaning process is performed on a clamping surface of the electrostatic platen; monitor a characteristic of current being supplied by the electrode power supply to the electrostatic platen; and perform an action when the characteristic of current is less than a predetermined threshold. In some embodiments, the action comprises terminating the cleaning process. In some embodiments, the action comprises providing an indication that the characteristic of current is less than a predetermined threshold to an operator. In some embodiments, the characteristic of current comprises peak current. In some embodiments, the characteristic of current comprises RMS current.

### BRIEF DESCRIPTION OF THE FIGURES

For a better understanding of the present disclosure, reference is made to the accompanying drawings, which are incorporated herein by reference and in which:

FIG. 1A-1B are semiconductor processing systems that may utilize the disclosed cleaning process;

FIG. 2 shows the current when a clamping voltage is applied to a platen without a workpiece at different levels of deposition;

FIG. 3 shows a sequence to determine when cleaning is warranted; and

FIG. 4 shows a sequence to determine when a cleaning process may be terminated.

### DETAILED DESCRIPTION

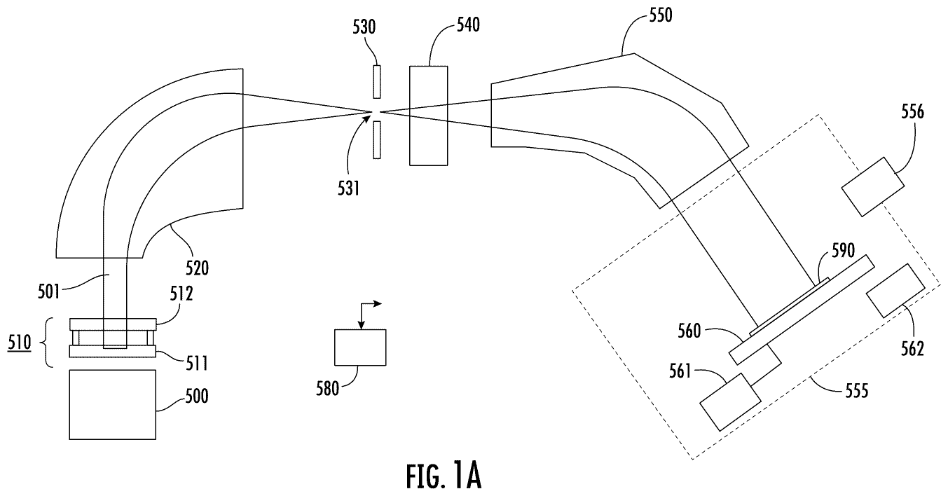

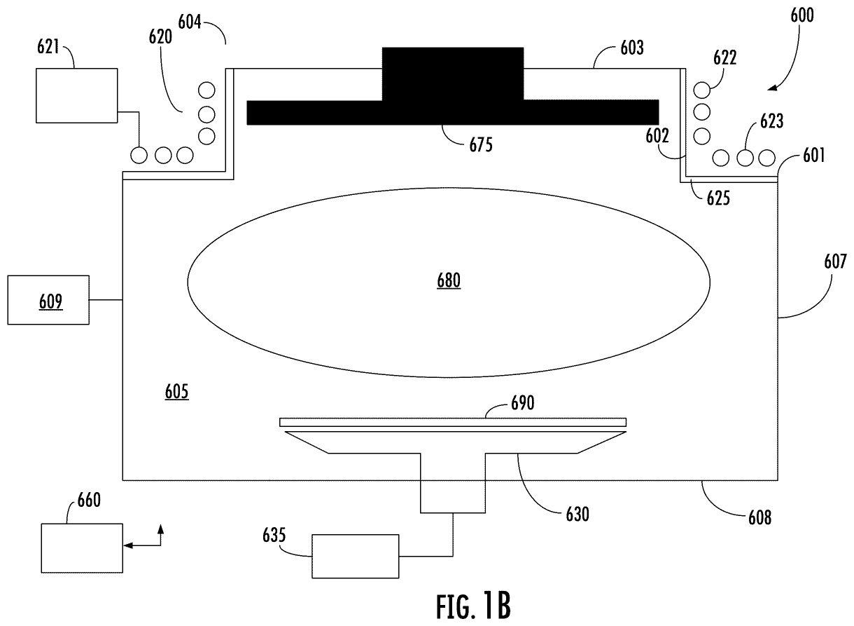

As noted above, the platen cleaning process may be used with a semiconductor processing system, such as those shown in FIGS. 1A-1B. As seen in FIG. 1A, the semiconductor processing system may include an ion source 500, which is used to generate an ion beam. The ion source 500 may be an indirectly heated cathode (IHC) ion source, a capacitively coupled plasma source, an inductively coupled plasma source, or a different source. Disposed outside and proximate the extraction aperture of the ion source 500 are extraction optics 510. In certain embodiments, the extraction optics 510 comprise one or more electrodes, including extraction electrode 511. In certain embodiments, the extraction optics 510 may comprise a second electrode 512 which may be biased at a different voltage than extraction electrode 511. In some embodiments, in excess of two electrodes, such as three electrodes or four electrodes may be employed. In these embodiments, the electrodes may be functionally and structurally similar to those described above, but may be biased at different voltages. These electrodes may each be mounted to a mounting flange.

Located downstream from the extraction optics 510 is a mass analyzer 520. The mass analyzer 520 uses magnetic fields to guide the path of the extracted ions 501. The magnetic fields affect the flight path of ions according to their mass and charge. A mass resolving device 530 that has a resolving aperture 531 is disposed at the output, or distal end, of the mass analyzer 520. By proper selection of the magnetic fields, only those extracted ions 501 that have a selected mass and charge will be directed through the resolving aperture 531. Other ions will strike the mass resolving device 530 or a wall of the mass analyzer 520 and will not travel any further in the system.

One or more beamline components may be disposed downstream from the mass resolving device 530. For example, a collimator 540 may be disposed downstream from the mass resolving device 530. The collimator 540 accepts the extracted ions 501 that pass through the resolving aperture 531 and creates a ribbon ion beam formed of a plurality of parallel or nearly parallel beamlets. In other embodiments, the ion beam may be a spot beam. In this embodiment, an electrostatic scanner may be disposed downstream from the mass resolving device 530 and may be used to move the spot beam in a first direction, as defined below.

Located downstream from the collimator 540 may be an acceleration/deceleration stage 550. The acceleration/deceleration stage 550 may be an electrostatic filter. The electrostatic filter is a beam-line lens component configured to independently control deflection, deceleration, and focus of the ion beam. The acceleration/deceleration stage 550 may comprise a plurality of electrodes, in the form of electrically biased rods, that are used to manipulate the ion beam. The output from the acceleration/deceleration stage 550 may be a ribbon ion beam having a width in the first direction, which is much greater than its height in the second direction. Located downstream from the acceleration/deceleration stage 550 is the platen 560.

The ion beam enters a process chamber 555. The process chamber 555 may include a load lock 556 that is used to move workpieces from an atmospheric environment to the vacuum conditions within the process chamber 555. A robot 562 may be used to transfer workpieces from the load lock 556 to and from the platen 560.

A platen 560 may be disposed within the process chamber 555. The platen 560 is an electrostatic clamp that includes a plurality of electrodes embedded under the top surface. An electrode power supply 561 is used to provide a clamping voltage to the electrodes. In some embodiments, there may be a plurality of electrodes, each of which is provided with a pulsed voltage, such as a square wave. To achieve the desired clamping force, the clamping voltage applied to each electrode may be the same amplitude and frequency, but may be offset in phase from the adjacent electrodes. In addition to providing the pulsed voltage to each electrode, the electrode power supply 561 also monitors the amount of current being supplied to the electrodes.

The workpiece 590, which may be, for example, a silicon wafer, a silicon carbide wafer, or a gallium nitride wafer, is disposed on the clamping surface of the platen 560. In some embodiments, the platen 560 may be moved in the second direction, which is perpendicular to the first direction, to allow the entirety of the workpiece 590 to be processed by the ion beam.

The semiconductor processing system also includes a controller 580. The controller 580 has a processing unit and an associated memory device. This memory device contains the instructions, which, when executed by the processing unit, enable the semiconductor processing system to perform the functions described herein. This memory device may be any non-transitory storage medium, including a non-volatile memory, such as a FLASH ROM, an electrically erasable ROM or other suitable devices. In other embodiments, the memory device may be a volatile memory, such as a RAM or DRAM. In certain embodiments, the controller 580 may be a general purpose computer, an embedded processor, or a specially designed microcontroller. The actual implementation of the controller 580 is not limited by this disclosure. The controller may be in communication with various components within the semiconductor processing system, such as the electrode power supply 561.

Further, while FIG. 1A shows a beam line system for ion implantation, it is understood that there are other types of semiconductor processing systems. For example, FIG. 1B shows a second embodiment of a semiconductor processing system.

FIG. 1B shows a cross-section of an embodiment of a plasma chamber 605 of a semiconductor processing system 600 that may be used with the present disclosure. This semiconductor processing system 600 may be used to perform deposition, etching or plasma doping. The semiconductor processing system 600 includes a plasma chamber 605 defined by a base 608, and several plasma chamber walls 607, which may be constructed from aluminum, graphite or another suitable material. In some embodiments, the plasma chamber 605 may be cylindrical. This plasma chamber 605 may be supplied with one or more feed gasses, that enter the plasma chamber 605 via a gas baffle 675 to create plasma 680.

This feedgas may be energized by an RF antenna 620 or another plasma generation mechanism. The RF antenna 620 is in electrical communication with a RF power supply 621 which supplies power to the RF antenna 620. A dielectric window 625, such as a quartz or alumina window, may be disposed between the RF antenna 620 and the interior of the plasma chamber 605.

In this embodiment, the top wall 604 of the semiconductor processing system 600 includes lower top surface 601, a vertical top surface 602, and an upper top surface 603. The vertical top surface 602 may be cylindrical. The gas baffle 675 may be attached to the upper top surface 603. The RF antenna 620 may include coils 622 that are arranged along the vertical top surface 602 and coils 623 that are arranged along the lower top surface 601. In some embodiments, the coils may be disposed adjacent to only one of these two surfaces. In some embodiments, the vertical top surface 602 is also made of a dielectric material.

Additionally, a remote chamber 609 may be in communication with the plasma chamber 605. This remote chamber 609 may be used to generate a remote plasma that is used for the cleaning of the plasma chamber 605.

A workpiece 690 is disposed within the plasma chamber 605, on the clamping surface of an electrostatic platen 630. The electrostatic platen 630 is supported by the base 608 and is in electrical communication with an electrode power supply 635, which may be used to provide electrostatic clamping to the electrostatic platen 630. As described above, a plurality of electrodes may be embedded under the top surface of the electrostatic platen 630. The electrode power supply 635 provides the clamping voltage to the electrodes. As described above, in some embodiments, there may be a plurality of electrodes, each of which is provided with a pulsed voltage, such as a square wave. To achieve the desired clamping force, the clamping voltage applied to each electrode may be the same amplitude and frequency, but may be offset in phase from the adjacent electrodes. In addition to providing the pulsed voltage to each electrode, the electrode power supply 635 also monitors the amount of current being supplied to the electrodes.

A controller 660 may be in communication with the electrode power supply 635, and other power supplies and valves. Similar to the controller described above, the controller 660 may include a processing unit, such as a microcontroller, a personal computer, a special purpose controller, or another suitable processing unit. The controller 660 may also include a non-transitory computer readable storage element, such as a semiconductor memory, a magnetic memory, or another suitable memory. This non-transitory storage element may contain instructions and other data that allows the controller 660 to perform the functions described herein.

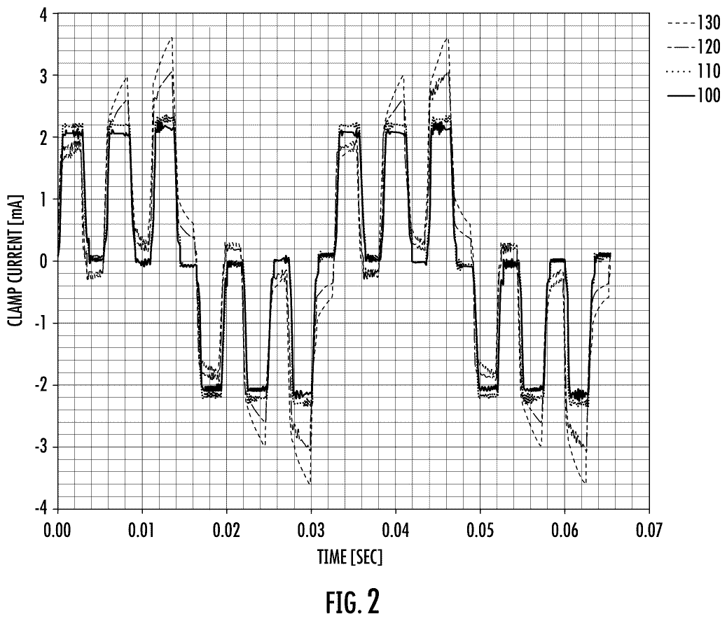

Unexpectedly, it has been found that the current waveform of the clamping voltage varies based on the amount of material that has been deposited on the platen. More specifically, a clamping voltage is applied to the platen when a workpiece is not disposed on the platen. The current associated with this clamping voltage was found to change based on the amount of material that has been deposited on the platen. FIG. 2 shows the current associated with the clamping voltage applied when a workpiece is not disposed on the platen. Line 100 represents a new platen which has not yet been used. Line 120 shows the current associated with the clamping voltage as material is being deposited on the surface of the platen. Line 130 shows the current associated with the clamping voltage wherein the amount of material that has been deposited on the surface of the platen affects the clamping of a workpiece. Note that as material is deposited on the platen, the characteristics of the current, such as peak current (both positive and negative) and RMS value become larger. Specifically, rather than being a square wave, as seen in line 100, the current profile becomes irregular, with the peak current increasing by 50% or more. This observation may be used to improve the cleaning process in several ways.

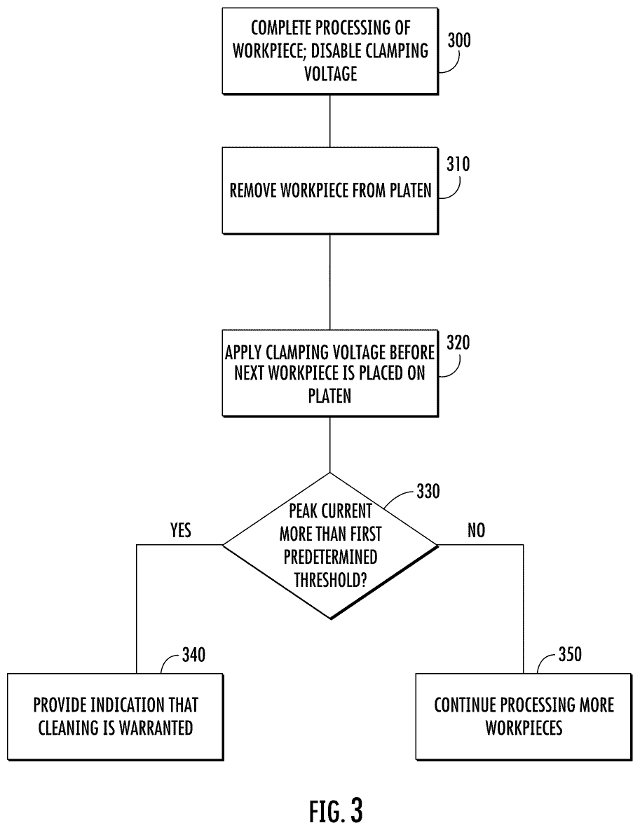

FIG. 3 shows a first improvement to the cleaning process. This improvement applies to the semiconductor processing systems shown in both FIG. 1A and FIG. 1B. This sequence allows automatic detection of when a cleaning process should be initiated. Currently, cleaning may be initiated based on visual evidence or based on a fixed metric, such as elapsed time or number of workpieces processed. However, the observations noted above may be used to determine when cleaning may be initiated. First, as shown in Box 300, the processing of the current workpiece is completed. The clamping voltage is then disabled to allow the workpiece to be removed. Next as shown in Box 310, the workpiece is removed from the process chamber 555 or plasma chamber 605. As seen in FIG. 1A, this may be done using robot 562. Before the next workpiece is placed on the platen, the controller enables the electrode power supply to apply the clamping voltage to the platen, as shown in Box 320. The electrode power supply monitors the amount of current that is being supplied to the platen. This information may be provided to the controller. The controller then compares the current profile to a first predetermined threshold, as shown in Decision Box 330. This first predetermined threshold may be calculated in various ways. In one embodiment, when a new platen is installed, a test is performed to check the peak current when the clamping voltage is applied to the platen without a workpiece. This peak value may be defined as the reference peak current. The first predetermined threshold may then be defined based on this reference peak current. In some embodiments, the first predetermined threshold may be a percentage of the reference peak current, such as between 50% and 100%, added to the reference peak current. In other words, the first predetermined threshold may be 150% to 200% of the reference peak current. In other embodiments, the first predetermined threshold may be a fixed amount greater than the reference peak current, such as an amount between 0.5 and 1.0 milliamps. In certain embodiments, the relationship between the reference peak current and the first predetermined threshold may be determined empirically and may vary from the values presented above.

If the peak current is less than this first predetermined threshold, the processing of a new workpiece may proceed, as shown in Box 350. However, if the peak current is greater than this first predetermined threshold, the controller provides an indication that a cleaning process is warranted, as shown in Box 340. This indication may be an alert to an operator or another type of indication.

Note that the sequence of FIG. 3 may be performed after each workpiece is processed. In another embodiment, the sequence may be performed based on elapsed time since the last time the sequence was performed. In another embodiment, the sequence may be performed based on the number of workpieces that have been processed since the last time the sequence was performed. For example, this sequence may be performed after each lot of workpieces has been processed.

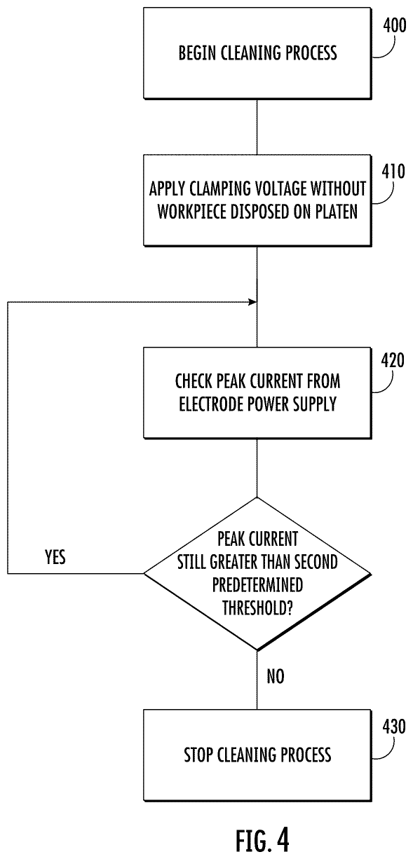

FIG. 4 shows a second improvement that may be made to the cleaning process. This improvement is directed toward an improved method to determine when the cleaning process may be terminated. This improvement also applies to the semiconductor processing systems shown in both FIG. 1A and FIG. 1B.

As shown in Box 400, a cleaning process is initiated. In the case of the semiconductor processing system of FIG. 1A, the cleaning process may comprise directing a sputtering species toward the platen 560 when a workpiece is not disposed on the platen 560. This sputtering species may be argon or another suitable species. In some embodiments, the sputtering species may be directed toward the platen 560 with an energy of up to 10 keV and a beam current of up to 10 mA. Of course, other energy and current values may be used, based on the implementation. The platen 560 may be positioned so that its clamping surface is perpendicular or at an angle to the incoming beam. In the semiconductor processing system of FIG. 1B, this cleaning process may involve the formation of a cleaning plasma that is used to remove material from the interior walls and the electrostatic platen 630. In some embodiments, this cleaning plasma may be generated within the plasma chamber 605. In other embodiments, the remote chamber 609 is used to generate a cleaning plasma which is introduced in the plasma chamber 605 due to a pressure differential between the remote plasma source and the plasma chamber 605. In both embodiments, this cleaning plasma may include a halogen, such as fluorine. For example, gasses such SF₆, NF₃ or others may be used. Note that in both systems, there is no workpiece disposed on the platen such that the clamping surface is exposed to the cleaning process.

In both embodiments, during this cleaning process, the clamping voltage may be applied to the platen by the electrode power supply, as shown in Box 410. Further, the electrode power supply monitors the current being supplied to the platen during the cleaning process. The monitoring may be performed continuously, or may be at a lower frequency. For example, the current may be monitored at regular intervals, such as every minute, or another suitable duration. Similarly, the clamping voltage may be applied continuously or at a lower frequency. This information may be provided to the controller. The controller then compares the peak current to a second predetermined threshold, as shown in Box 420. This second predetermined threshold may be calculated in various ways. The second predetermined threshold may be defined based on the reference peak current, which was determined as explained above. In some embodiments, the second predetermined threshold may be a percentage of the reference peak current, such as between 10% and 20% added to the reference peak current. In other words, the second predetermined threshold may be 110% to 120% of the reference peak current. In other embodiments, the second predetermined threshold may be a fixed amount greater than the reference peak current, such as 0.1 to 0.2 milliamps. In certain embodiments, the relationship between the reference peak current and the second predetermined threshold may be determined empirically and may vary from the values presented above. If the peak current is still greater than the second predetermined threshold, the cleaning process continues, and the controller continues monitoring the peak current. However, if the peak current is less than the second predetermined threshold, the cleaning process is complete, as shown in Box 430. In response, the controller performs an action. In some embodiments, for the system shown in FIG. 1A, the controller 580 directly terminates the cleaning process by disabling the ion beam. In the system of FIG. 1B, the controller 660 may terminate the flow of the remote plasma or of cleaning gas into the plasma chamber 605. In other embodiments, the controller provides an indication to an operator that the cleaning process is complete.

FIG. 2 shows the results of the sequence of FIG. 4. Line 130 represents the current profile when the cleaning process is initiated. In some embodiments, this cleaning process may be initiated based on the sequence shown in FIG. 3. As the cleaning process proceeds, the amount of material on the clamping surface of the platen is being removed. Consequently, the peak current is reduced, as shown in line 120. Line 110 represents the current profile when the cleaning process is terminated. Note that the cleaning is terminated when the peak current is below the second predetermined threshold, which may be slightly greater than the original reference peak current, which is shown in line 100.

While the above disclosure describes the use of peak current to initiate and control the cleaning process, other characteristics of the current may be used. For example, the controller 580 may compute the root mean square (RMS) value of the current. Like peak current, the RMS value increases as material is deposited on the clamping surface of the platen. If a different characteristic of the current is used, the reference value of this characteristic may be determined using the technique described above with respect to the reference peak current. Similarly, the first predetermined threshold and the second predetermined threshold may be calculated based on the reference value of that characteristic. For example, the first and second predetermined thresholds may be based on the reference RMS current.

Further, while the above disclosure described the determination of the predetermined thresholds based on reference values, it is understood that other techniques may be used. For example, in another embodiment, fixed values may be used for these predetermined thresholds.

Further, in certain embodiments, the controller may implement the sequence shown in FIG. 3 to determine when to initiate a cleaning process and may implement the sequence of FIG. 4 to terminate that cleaning process. In other embodiments, only one of these sequences may be implemented by the controller.

The system and method described herein have many advantages. Currently, there is no definitive end point for the cleaning process of an electrostatic platen. Cleaning processes that are too short in duration may not remove all of the deposited material. Cleaning processes that are too long in duration may damage the surface of the platen. Additionally, long cleaning processes also reduce throughput. By using the disclosed system and method, the cleaning process may be more accurately controlled.

Furthermore, the sequence shown in FIG. 3 may be used to more accurately determine when a cleaning process is warranted. In this way, a cleaning process is not initiated prematurely or after failures have already occurred.

The present disclosure is not to be limited in scope by the specific embodiments described herein. Indeed, other various embodiments of and modifications to the present disclosure, in addition to those described herein, will be apparent to those of ordinary skill in the art from the foregoing description and accompanying drawings. Thus, such other embodiments and modifications are intended to fall within the scope of the present disclosure. Furthermore, although the present disclosure has been described herein in the context of a particular implementation in a particular environment for a particular purpose, those of ordinary skill in the art will recognize that its usefulness is not limited thereto and that the present disclosure may be beneficially implemented in any number of environments for any number of purposes. Accordingly, the claims set forth below should be construed in view of the full breadth and spirit of the present disclosure as described herein.

What is claimed is:

1. A method of cleaning an electrostatic platen, comprising:
performing a cleaning process on a clamping surface of the electrostatic platen;
applying a clamping voltage to the electrostatic platen using an electrode power supply while the cleaning process is ongoing;
monitoring a characteristic of current being supplied by the electrode power supply to the electrostatic platen; and
performing an action when the characteristic of current is less than a predetermined threshold.

2. The method of claim 1, wherein the characteristic of current comprises peak current.

3. The method of claim 1, wherein the characteristic of current comprises RMS current.

4. The method of claim 1, wherein a reference value of the characteristic of current is determined by applying a clamping voltage to the electrostatic platen when first installed, and wherein the predetermined threshold is determined based on the reference value of the characteristic of current.

5. The method of claim 4, wherein the predetermined threshold is a percentage of the reference value added to the reference value.

6. The method of claim 4, wherein the predetermined threshold is a fixed value added to the reference value.

7. The method of claim 1, wherein the action comprises terminating the cleaning process.

8. The method of claim 1, wherein the action comprises providing an indication that the characteristic of current is less than the predetermined threshold to an operator.

9. The method of claim 1, wherein the cleaning process comprises directing an argon ion beam toward the clamping surface of the electrostatic platen.

10. The method of claim 1, wherein the cleaning process comprises utilizing a cleaning plasma in a plasma chamber containing the electrostatic platen.

11. A method of determining when to clean an electrostatic platen, comprising:
removing a workpiece from the electrostatic platen;
applying a clamping voltage to the electrostatic platen using an electrode power supply after removing the workpiece;
monitoring a characteristic of current being supplied by the electrode power supply to the electrostatic platen; and
determining that the electrostatic platen should be cleaned when the characteristic of current is greater than a predetermined threshold.

12. The method of claim 11, wherein the characteristic of current comprises peak current.

13. The method of claim 11, wherein the characteristic of current comprises RMS current.

14. The method of claim 11, wherein a reference value of the characteristic of current is determined by applying a clamping voltage to the electrostatic platen when first installed, and wherein the predetermined threshold is determined based on the reference value of the characteristic of current.

15. The method of claim 14, wherein the predetermined threshold is a percentage of the reference value added to the reference value or is a fixed value added to the reference value.

16. A semiconductor processing apparatus, comprising:
an electrostatic platen adapted to electrostatically clamp a workpiece;
an electrode power supply to provide a clamping voltage to the electrostatic platen; and
a controller, wherein the controller is configured to:
apply a clamping voltage to the electrostatic platen using the electrode power supply while a cleaning process is performed on a clamping surface of the electrostatic platen;
monitor a characteristic of current being supplied by the electrode power supply to the electrostatic platen; and
perform an action when the characteristic of current is less than a predetermined threshold.

17. The semiconductor processing apparatus of claim 16, wherein the action comprises terminating the cleaning process.

18. The semiconductor processing apparatus of claim 16, wherein the action comprises providing an indication that the characteristic of current is less than a predetermined threshold to an operator.

19. The semiconductor processing apparatus of claim 16, wherein the characteristic of current comprises peak current.

20. The semiconductor processing apparatus of claim 16, wherein the characteristic of current comprises RMS current.
